(19) United States
(12) Patent Application Publication
(10) Pub. No.: US 2024/0145361 A1
(43) Pub. Date: May 2, 2024

(54) SEMICONDUCTOR PACKAGE AND METHOD FOR FABRICATING THE SAME

(71) Applicant: SAMSUNG ELECTRONICS CO., LTD., SUWON-SI (KR)

(72) Inventors: WONBIN SHIN, Suwon-si (KR); JUNHYEONG PARK, Suwon-si (KR); JIHYE SHIM, Suwon-si (KR)

(21) Appl. No.: 18/361,219

(22) Filed: Jul. 28, 2023

(30) Foreign Application Priority Data
Oct. 28, 2022 (KR) 10-2022-0141510

(51) Int. Cl. H01L 23/498; H01L 21/48; H01L 21/56; H01L 23/00; H01L 23/31; H01L 25/10

(52) U.S. Cl. CPC H01L 23/49811; H01L 21/4853; H01L 21/4857; H01L 21/56; H01L 23/3128; H01L 23/49822; H01L 24/16; H01L 24/81; H01L 25/105; H01L 2224/16227; H01L 2224/81

(57) ABSTRACT

A semiconductor package may include: a first redistribution substrate; a semiconductor chip disposed on the first redistribution substrate; a second redistribution substrate; an encapsulant disposed between the first redistribution substrate and the second redistribution substrate and encapsulating the semiconductor chip; and a connection structure disposed in the encapsulant, connecting an upper surface of the first redistribution layer substrate and a lower surface of the second redistribution substrate, and to include a paste bump.

### CROSS-REFERENCE TO RELATED APPLICATION

This application claims priority under 35 U.S.C. § 119 to Korean Patent Application No. 10-2022-0141510, filed in the Korean Intellectual Property Office on Oct. 28, 2022, the disclosure of which is incorporated herein by reference herein in its entirety.

### TECHNICAL FIELD

The present disclosure relates to a semiconductor device having a connection structure and a fabricating method thereof.

### DISCUSSION OF RELATED ART

Many of the advances in the semiconductor industry relate to increasing integration density. With increased integration density more devices may be fit within a given area. Accordingly, there is an increasing need for packaging techniques for high density applications, such as a package-on-package (POP) structure. The package-on-package (POP) structure may be used to stack an upper semiconductor package on top of a lower semiconductor package.

In a conventional package-on-package (POP) structure, the lower semiconductor package (e.g., a fan-out wafer level package (FOWLP)) may be formed by mounting a semiconductor chip on a front-side redistribution layer (FRDL) structure and encapsulating the semiconductor chip. In this case, a back-side redistribution layer (BRDL) structure may be formed on the lower semiconductor package, and the upper semiconductor package or semiconductor chip may be mounted on the back-side redistribution layer structure.

In such a package-on-package (POP) structure, the front-side redistribution layer structure and the back-side redistribution layer structure are electrically connected through a conductive connection structure (e.g., Cu Post). A process of forming the connection structure on the front-side redistribution layer structure may include a plurality of photolithography and plating processes. Accordingly, the process of forming the package-on-package (POP) structure may be complicated and slow.

### SUMMARY

Aspects of the present disclosure provide a semiconductor device and a fabricating method thereof. The fabricating method may be a simplified process of electrically connecting a front redistribution line structure and a back-side redistribution line structure. The semiconductor device may include a connection structure capable of coping with a semiconductor chip having a large thickness.

According to some embodiments a semiconductor package may include: a first redistribution substrate; a semiconductor chip disposed on the first redistribution substrate; a second redistribution substrate; an encapsulant disposed between the first redistribution substrate and the second redistribution substrate and encapsulating the semiconductor chip; and a connection structure disposed in the encapsulant, connecting an upper surface of the first redistribution substrate and a lower surface of the second redistribution substrate, and including a paste bump.

The connection structure may electrically connect the first redistribution substrate and the second redistribution substrate.

The paste bump may have a cross-sectional area that decreases in a plan view from an upper portion to a lower portion.

The connection structure may further include a plating portion on at least one of an upper portion and a lower portion of the paste bump, and the paste bump may include a material different than that of the plating portion.

The connection structure may further include a first bonding pad on the upper surface of the first redistribution substrate, and the paste bump may connect the first bonding pad and the second redistribution substrate. The semiconductor package may further include a chip bump between the first redistribution substrate and the semiconductor chip, wherein the first bonding pad may protrude above a lower end of the semiconductor chip on the chip bump.

The connection structure may further include a conductive pillar extending from the lower surface of the second redistribution substrate, and the paste bump may connect the conductive pillar and the first redistribution substrate.

The conductive pillar may protrude below an upper end of the semiconductor chip.

The semiconductor package may further include an upper package disposed on an upper surface of the second redistribution substrate, and a bonding member of the upper package may be connected to a second bonding pad disposed on the upper surface of the second redistribution substrate to electrically connect the upper package to the second redistribution substrate.

The semiconductor package may further include a package bump disposed on a lower surface of the first redistribution substrate.

According to some embodiments a semiconductor package may include: a first redistribution substrate; a semiconductor chip disposed on the first redistribution substrate; a chip bump connecting the first redistribution substrate and the semiconductor chip; a second redistribution substrate; an encapsulant disposed between the first redistribution substrate and the second redistribution substrate and encapsulating the semiconductor chip; and a connection structure configured to include a paste bump penetrating the encapsulant and electrically connecting an upper surface of the first redistribution substrate and a lower surface of the second redistribution substrate, wherein at least a portion of the paste bump may have a cross-sectional area decreasing in a plan view from an upper portion to a lower portion; and a package bump disposed on a lower surface of the first redistribution substrate.

The paste bump may include an alloy comprising tin.

According to some embodiments a method of fabricating a semiconductor device may include: preparing a first redistribution substrate on which a semiconductor chip is disposed; preparing an encapsulant comprising a pillar structure including a paste bump penetrating the encapsulant; and encapsulating the semiconductor chip by stacking the encapsulant on the first redistribution substrate.

The preparing of the first redistribution substrate may include: forming a first redistribution substrate on a first carrier; and bonding the semiconductor chip on the first redistribution substrate.

The preparing of the encapsulant may include: forming the pillar structure by printing the paste bump on a second carrier; and forming the encapsulant, in a semi-cured state, on the second carrier, wherein the pillar structure penetrates the encapsulant.

The forming of the pillar structure may include: forming a conductive pillar on the second carrier, and printing the paste bump on the conductive pillar.

The preparing of the encapsulant may include: forming a second redistribution substrate on a second carrier; forming the pillar structure by printing the paste bump on the second redistribution substrate; and forming the encapsulant, in a semi-cured state, on the second redistribution substrate, wherein the pillar structure may penetrate the encapsulant.

The forming of the pillar structure may include: forming a conductive pillar on the second redistribution substrate, and printing the paste bump on the conductive pillar.

In the encapsulating, the paste bump may be connected to a bonding pad positioned on the first redistribution substrate.

A method may further include forming a second redistribution substrate on the encapsulant.

According to an embodiment, it may be possible to reduce process time and cost by simplifying a manufacturing process of a connection structure that electrically connects a front redistribution line structure and a back-side redistribution line structure of a semiconductor package.

In addition, a height of such a connection structure may be easily increased, and it may correspond to a semiconductor chip with a large thickness.

### BRIEF DESCRIPTION OF THE DRAWINGS

FIG. 1 illustrates a cross-sectional view of a semiconductor package according to an embodiment.

FIG. 2 to FIG. 8 each illustrate a fabricating method of a semiconductor package according to an embodiment.

FIG. 9 to FIG. 11 each illustrate a fabricating method of a semiconductor package according to another embodiment.

FIG. 12 and FIG. 13 each illustrate a fabricating method of a semiconductor package according to another embodiment.

FIG. 14 to FIG. 15 each illustrate a fabricating method of a semiconductor package according to another embodiment.

FIG. 16 and FIG. 17 each illustrate a fabricating method of a semiconductor package according to another embodiment.

FIG. 18 illustrates a semiconductor package having a package-on-package structure to which an embodiment is applied.

### DETAILED DESCRIPTION

Aspects of the present disclosure will be described more fully hereinafter with reference to the accompanying drawings, in which exemplary embodiments of the invention are shown. As those skilled in the art would realize, exemplary embodiments may be modified in various ways, all without departing from the spirit or scope of the present disclosure.

The drawings and description are to be regarded as illustrative in nature and not restrictive. Like reference numerals designate like elements throughout the specification.

Further, since sizes and thicknesses of constituent members shown in the accompanying drawings are arbitrarily given for better understanding and ease of description, embodiments of the present disclosure are not limited to the illustrated sizes and thicknesses.

Throughout this specification and the claims that follow, when it is described that an element is “coupled/connected” to another element, the element may be “directly coupled/connected” to the other element or “indirectly coupled/connected” to the other element through a third element. In addition, unless explicitly described to the contrary, the word “comprise” and variations such as “comprises” or “comprising” will be understood to imply the inclusion of stated elements but not the exclusion of any other elements.

It will be understood that when an element such as a layer, film, region, or substrate is referred to as being “on” another element, it can be directly on the other element or intervening elements may also be present. In contrast, when an element is referred to as being “directly on” another element, there are no intervening elements present. Further, in the specification, the word “on” or “above” means positioned on or below the object portion, and does not necessarily mean positioned on an upper side of the object portion based on a gravitational direction.

Further, throughout the specification, the phrase “in a plan view” refers to an object portion viewed from above, and the phrase “in a cross-sectional view” refers to a cross-section taken by vertically cutting an object portion and viewed from the side.

Hereinafter, one or more embodiments of a semiconductor package will be described with reference to drawings.

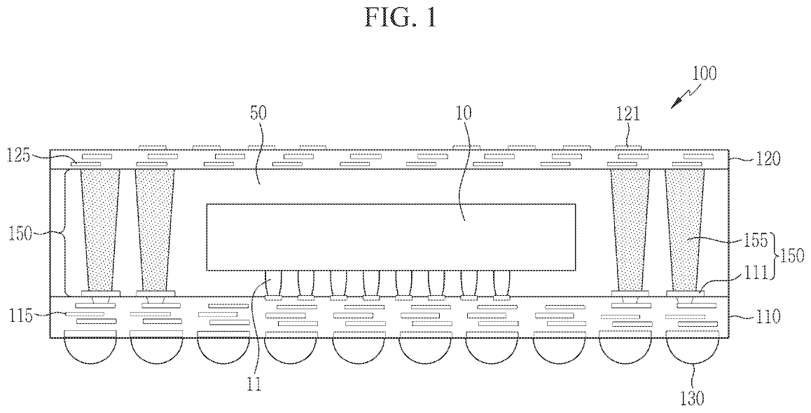

FIG. 1 illustrates a cross-sectional view of a semiconductor package according to an embodiment.

Referring to FIG. 1, the semiconductor package 100 includes a first redistribution substrate 110, a first semiconductor chip 10, a second redistribution substrate 120, a connection structure 150, and an encapsulant 50.

The first redistribution substrate 110 may be a front-side redistribution layer (RDL) structure including a plurality of insulating layers and a plurality of first redistribution layers (RDLs) 115.

The first semiconductor chip 10 may be bonded to the first redistribution substrate 110 through a chip bump 11. The first semiconductor chip 10 may be electrically connected to the first redistribution substrate 110 through the chip bump 11.

The second redistribution substrate 120 may be positioned on the first semiconductor chip 10. The second redistribution substrate 120 may be positioned in parallel with the first redistribution substrate 110. The second redistribution substrate 120 may be a back-side RDL structure. The back-side RDL structure may include a plurality of insulating layers and a plurality of second redistribution layers 125.

Meanwhile, in the present specification, “upper portion”, “lower portion”, “upper surface”, and “lower surface” are defined based on an orientation of the semiconductor package 100 illustrated in FIG. 1.

The connection structure 150 may be a portion that electrically connects the first redistribution substrate 110 and the second redistribution substrate 120. The connection structure 150 may be spaced apart from the first semiconductor chip 10. The connection structure 150 may connect an upper surface of the first redistribution substrate 110 and a lower surface of the second redistribution substrate 120. The connection structure 150 may have a pillar shape, for example. At least a portion of the connection structure 150 has a smaller cross-sectional area in a plan view from an upper portion to a lower portion.

According to an embodiment, the connection structure 150 may include a paste bump 155. The paste bump 155 of the connection structure 150 may be hardened or cured. Referring to FIG. 1, the connection structure 150 may include a first bonding pad 111 and the paste bump 155. The first bonding pad 111 may be formed on the upper surface of the first redistribution substrate 110. The paste bump 155 may connect the first bonding pad 111 and the second redistribution substrate 120. The paste bump 155 may be formed of a conductive paste containing conductive metal particles. In an example where the first bonding pad 111 is electrically connected to the first redistribution layers 115 and the paste bumps 155 are electrically connected to the second redistribution layers 125, the first redistribution substrate 110 and the second redistribution substrate 120 may be electrically connected to one another through the connection structure 150.

According to an embodiment, the paste bump 155 may be formed through a printing process. The paste bump 155 formed through the printing process may have a shape in which a cross-sectional area thereof in a plan view decreases as a distance from a printing surface thereof increases. The cross-sectional area of the paste bump 155 in a plan view may decrease gradually as a distance from a printing surface thereof increases. For example, a shape of the paste bump 155 may be similar to a truncated cone. Accordingly, a portion of the connection structure 150 formed of the paste bump 155 may have a shape in which a cross-sectional area thereof in a plan view decreases from an upper portion to a lower portion with respect to the semiconductor package 100. That is, an upper cross-sectional area may have a larger shape than a lower cross-sectional area.

In an embodiment in which the paste bump 155 is not printed on the first redistribution substrate 110 but is printed on a separate carrier, a process of forming the paste bump 155 may be performed in parallel with a process of bonding the first semiconductor chip 10. In addition, a height of the connection structure 150 may be adjusted to correspond to a height of the first semiconductor chip 10. That is, the height of the connection structure 150 may be greater than the height of the first semiconductor chip 10.

The encapsulant 50 may be disposed between the first redistribution substrate 110 and the second redistribution substrate 120. The encapsulant 50 may encapsulate the first semiconductor chip 10 and surround a portion of the connection structure 150. That is, the connection structure 150 may have a structure penetrating the encapsulant 50.

Hereinafter, an example fabricating method of a semiconductor package according to an embodiment will be described.

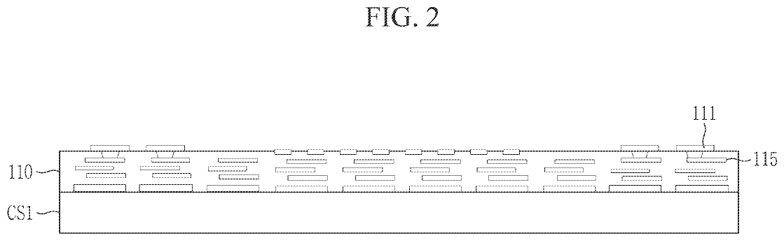

FIG. 2 to FIG. 8 each illustrate a fabricating method of a semiconductor package according to an embodiment. FIG. 2 to FIG. 8 each illustrate a cross-sectional view for ease of understanding. In addition, although only one semiconductor package portion may be illustrated in the drawings for convenience of understanding, a wafer level process may be included.

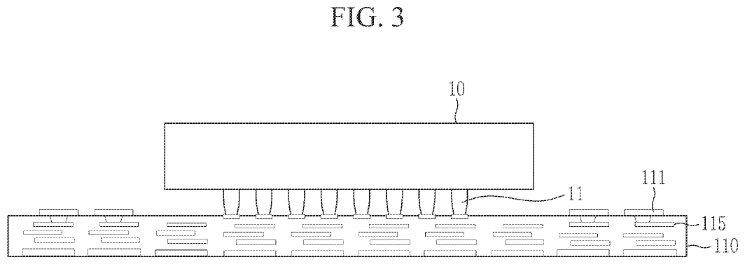

FIG. 2 and FIG. 3 illustrate preparing a first redistribution substrate 110 on which a first semiconductor chip 10 may be positioned in a method of fabricating a semiconductor package according to an embodiment.

Referring to FIG. 2, the first redistribution substrate 110 may be formed on a first carrier CS1. The first redistribution substrate 110 may include a plurality of insulating layers (not illustrated), a plurality of first redistribution layers 115, and a plurality of vias (not illustrated) forming electrical connections between the first redistribution layers 115. The insulating layers may include, for example, at least one of a silicon-based insulating material such as a silicon oxide or a silicon nitride, a polymer such as polybenzoxazole (PBO), benzocylobutene (BCB) or polyimide, and a nitride such as phosphosilicate glass (PSG) or borophosphosilicate glass (BPSG). The first redistribution layer 115 may be formed of, for example, at least one of copper, aluminum, nickel, titanium, and alloys thereof. The vias may be formed of, for example, copper, a copper-containing composition, or a copper alloy. Alternatively, the vias may be formed of a material such as aluminum or nickel.

The first bonding pad 111 may be disposed on an upper surface of the first redistribution substrate 110. As shown in FIG. 1, the first bonding pad 111 may be electrically connected to the second redistribution substrate 120, where the paste bump 155 of the connection structure 150 may directly contact the first bonding pad 111. The first bonding pad 111 may be disposed on the upper surface of the first redistribution substrate 110. The first bonding pad 111 may be exposed on the upper surface of the first redistribution substrate 110. The first bonding pad 111 may be formed, for example, through a photolithography process and a plating process. The first bonding pad 111 may be formed by other methods, which are not limited methods described herein. The first bonding pad 111 may be part of the connection structure 150.

Referring to FIG. 3, the first semiconductor chip 10 may be positioned in the first redistribution substrate 110. The first semiconductor chip 10 may be bonded to the first redistribution substrate 110. For example, the first semiconductor chip 10 may be electrically connected to the first redistribution substrate 110 through the chip bump 11. Although one first semiconductor chip 10 is illustrated in the drawings, embodiments of the present disclosure are not limited thereto, and a plurality of semiconductor chips may be disposed on the first redistribution substrate 110.

According to an embodiment, the first carrier CS1 on a lower surface of the first redistribution substrate 110 may be removed. In an embodiment, in a subsequent process, a protective means, e.g., a protective film, may be formed on the lower surface of the first redistribution substrate 110. The protective film may protect the lower surface of the first redistribution substrate 110.

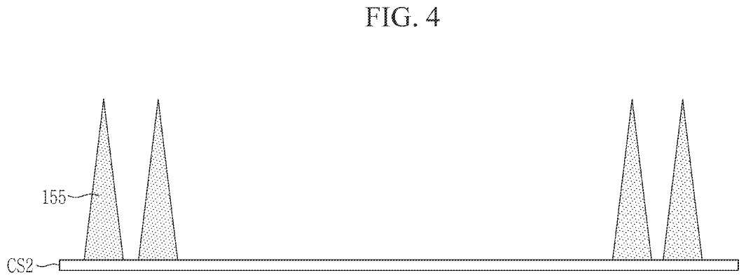

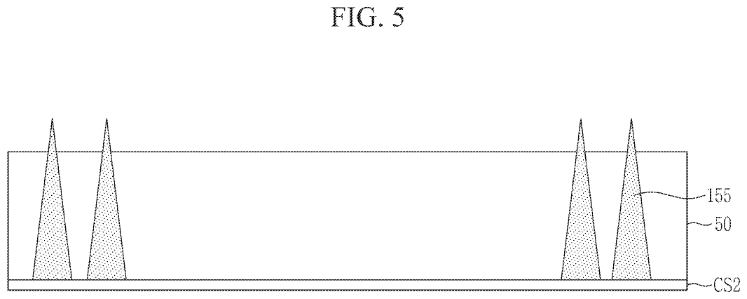

FIG. 4 and FIG. 5 illustrate a step of preparing the paste bump 155 and the encapsulant 50 in a method of fabricating a semiconductor package according to an embodiment.

Referring to FIG. 4, the paste bump 155 may be formed on a second carrier CS2. The paste bump 155 may be formed of, for example, a conductive paste containing flux and conductive metal particles. The conductive paste may have a thermal curing property that is cured when heat is applied. The conductive metal particles may include, for example, silver, copper, tin, indium, or nickel. For example, the conductive metal particles of the paste bump 155 may be formed of an alloy containing tin.

In an embodiment, in a process of forming the paste bump 155, a mask having a hole formed at a position where the paste bump 155 is to be formed may be positioned on the second carrier CS2, and a conductive paste may be printed on the second carrier CS2. For example, the conductive paste may be printed on the second carrier CS2 by using a squeegee. A printing step may be repeated a plurality of times to form the paste bump 155 having a predetermined height. In an embodiment, the paste bump 155 having a columnar shape may be formed on the second carrier CS2 through a printing process, and the paste bump 155 printed on the second carrier CS2 may be cured through a reflow process, for example.

The paste bump 155 as printed may be cured as a flux is evaporated by heat. Thereby, the paste bump 155, as cured, may have a metal column shape. According to an embodiment, the printed (or cured) paste bump 155 may be in a state in which conductive metal particles, e.g., grains, are non-uniformly arranged and may have non-uniform sizes. According to an embodiment, the printed (or cured) paste bump 155 may be in a state in which conductive metal particles are uniformly arranged and may have a uniform size. Different combinations of particle uniformity and particle size may be used in different implementations.

As illustrated in FIG. 4, the paste bump 155 may be formed in a cone or truncated cone shape, or a shape similar thereto. The paste bump 155 may be formed having a cross-sectional area in a plan view that becomes smaller as distance from the second carrier CS2 increases.

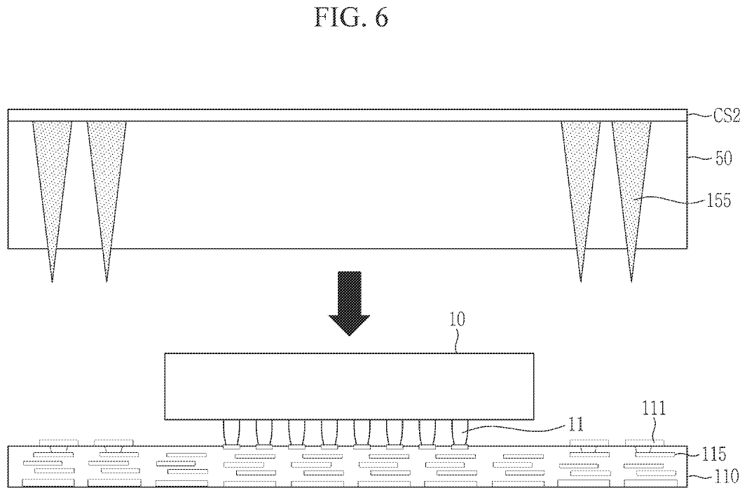

Referring to FIG. 5, the paste bump 155 may penetrate the encapsulant 50. The encapsulant 50 may be stacked on the second carrier CS2. According to an embodiment, the encapsulant 50 may be in a semi-cured state. For example, the encapsulant 50 may be a B-Stage material, for example, a B-Stage resin. The encapsulant 50, as applied to the second carrier CS2, may have a fluidity and an elasticity. For example, the encapsulant 50 may have a hardness lower than a hardness of the paste bump 155, as cured, and may be in the form of a film. The paste bump 155, which may be cured, may penetrate the encapsulant 50. The encapsulant 50 may completely surround an upper portion of the paste bump 155. A lower portion of the paste bump 155 may extend from a lower surface of the encapsulant 50 (see FIG. 6). The encapsulant 50, as applied in the semi-cured state, may be cured by applying heat in a subsequent process that may include encapsulating the first semiconductor chip 10.

The encapsulant 50 may include a molding compound, a molding underfill, an epoxy and/or a resin, and may be, for example, an epoxy molding compound (EMC).

Preparing the paste bump 155 and encapsulant 50 illustrated in FIG. 4 and FIG. 5 may be performed in parallel with the preparing of the first redistribution substrate 110 on which the first semiconductor chip 10 is positioned, as illustrated in FIG. 2 and FIG. 3. Accordingly, it may be possible to reduce a time for the fabricating process of the semiconductor package according to an embodiment.

FIG. 6 to FIG. 8 illustrate encapsulating and packaging of the first semiconductor chip 10 in a fabricating method of a semiconductor package according to an embodiment.

Referring to FIG. 6, the encapsulant 50 may be stacked on the first redistribution substrate 110 on which the first semiconductor chip 10 is positioned. According to an embodiment, the paste bump 155, which may be cured, penetrates the encapsulant 50, which may be in a B-Stage (or semi-cured) state, and the second carrier CS2 including the paste bump 155 and the encapsulant 50 may be laminated on the first redistribution substrate 110. In an embodiment, portions of the paste bumps 155 extending from the lower surface of the encapsulant 50 may be pressed into the first bonding pads 111, forming the connection structure 150.

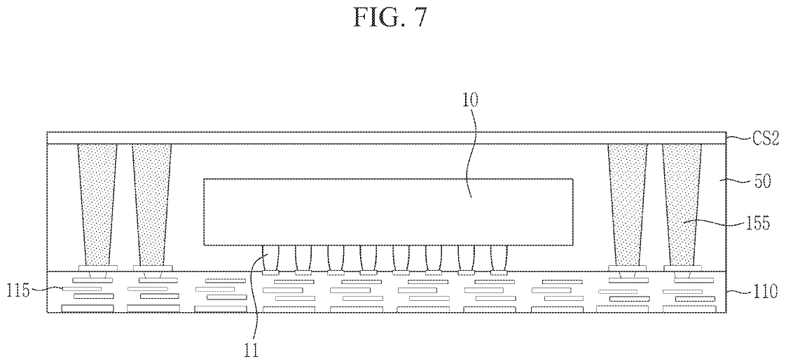

Referring to FIG. 7, the encapsulant 50 between the first redistribution substrate 110 and the second carrier CS2 may encapsulate the first semiconductor chip 10. According to an embodiment, the encapsulant 50 in the B-Stage (or semi-cured) state may be laminated on the first redistribution substrate 110, and the encapsulant 50 may fill a space between the first redistribution substrate 110 and the second carrier CS2. For example, in a heating and curing process, the encapsulant 50 may fill a space between the first redistribution substrate 110 and the second carrier CS2 such that there is no empty space between the first redistribution substrate 110 and the second carrier CS2.

Referring to FIG. 7, the paste bump 155 may be connected to the first bonding pad 111 on the first redistribution substrate 110. To this end, when the semi-cured encapsulant 50, through which the paste bump 155 penetrates, is laminated on the first redistribution substrate 110, a position of the paste bump 155 may correspond to a position of the first bonding pad 111.

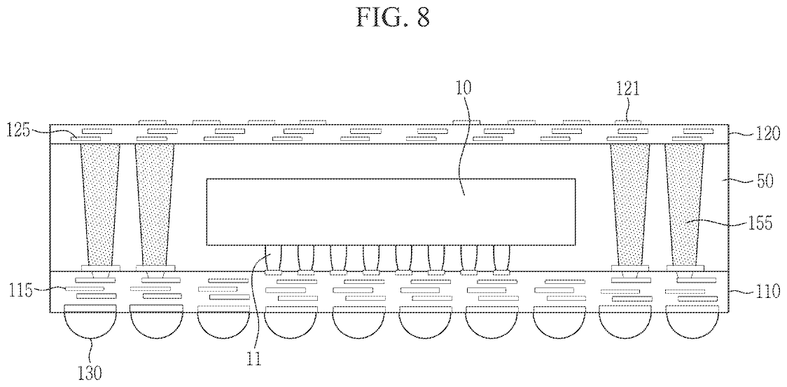

Referring to FIG. 8, the second carrier CS2 may be removed from the encapsulant 50. In an embodiment, after removing the second carrier CS2 on the encapsulant 50, the second redistribution substrate 120 may be formed on the encapsulant 50. The second redistribution substrate 120 may be formed in a substantially similar manner as the first redistribution substrate 110 described herein. Accordingly, the second redistribution substrate 120 may include a plurality of insulating layers (not illustrated), a plurality of second redistribution layers 125, and a plurality of vias (not illustrated) forming electrical connections between the second redistribution layers 125.

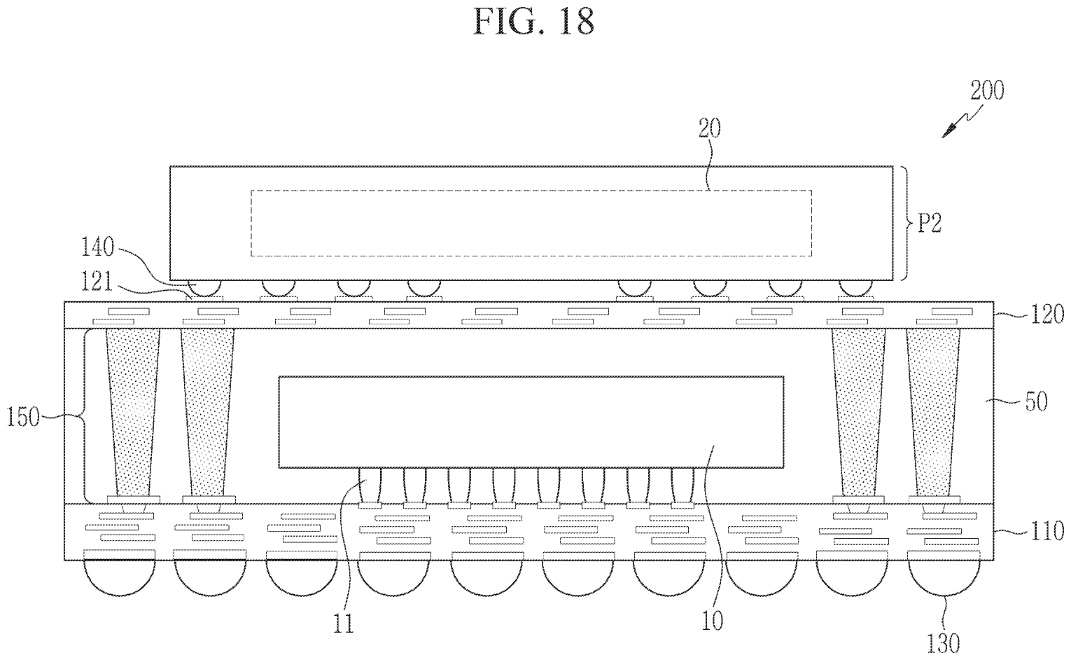

The second bonding pad 121 may be disposed on an upper surface of the second redistribution substrate 120. The second bonding pad 121 may electrically connect a second semiconductor chip 20 (see FIG. 18) positioned on the second redistribution substrate 120, or another semiconductor package P2 (see FIG. 18), to the second redistribution substrate 120. The second bonding pad 121 may be disposed on the upper surface of the second redistribution substrate 120 and exposed to the outside. The second bonding pad 121 may be formed, for example, through a photolithography process and a plating process, but is not limited thereto. The second bonding pad 121 may be electrically connected to a bonding member 140 (see FIG. 18), which may be electrically connected to the second semiconductor chip 20 (see FIG. 18) or another semiconductor package P2 (see FIG. 18).

A package bump 130 may be formed on a lower surface of the first redistribution substrate 110. The package bump 130 may be a portion that connects the semiconductor package 100 to an external circuit (not illustrated). The package bump 130 may be electrically connected to the first redistribution substrate 110. The package bump 130 may include solder, e.g., a solder ball, for example.

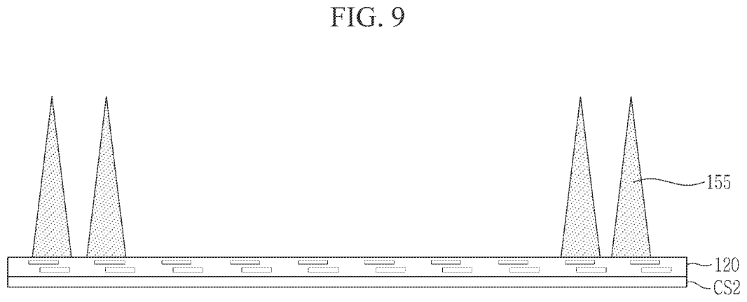

FIG. 9 to FIG. 11 illustrate a fabricating method of a semiconductor package according to an embodiment. In an embodiment of FIG. 9 to FIG. 11, the second redistribution substrate 120 may be formed in advance.

Referring to FIG. 9, the second redistribution substrate 120 may be formed (printed) on the second carrier CS2 and the paste bump 155 may be formed on the second redistribution substrate 120. For example, the paste bump 155 may not be formed directly on the second carrier CS2. For example, the paste bump 155 may be formed on the second redistribution substrate 120 after the second redistribution substrate 120 may be formed on the second carrier CS2. Accordingly, misalignment between the paste bump 155 and the second redistribution substrate 120 may be substantially prevented.

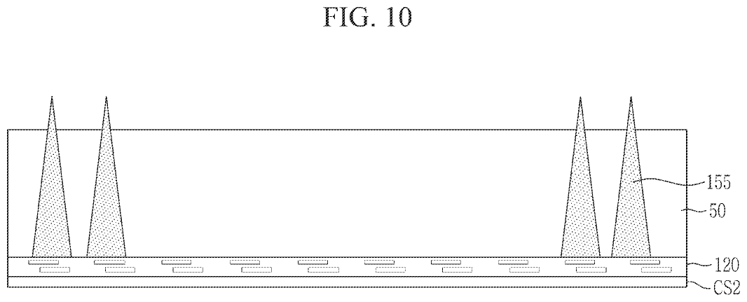

Referring to FIG. 10, the encapsulant 50 may be formed on the second redistribution substrate 120. In this case, the paste bump 155, which may be cured, may penetrate the semi-cured encapsulant 50.

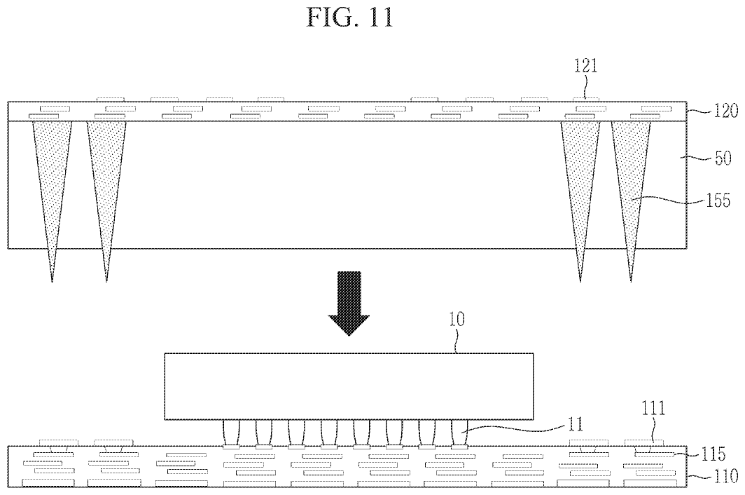

Referring to FIG. 11, the second carrier CS2 may be removed, and the second bonding pad 121 may be formed on an upper surface of the second redistribution substrate 120. In addition, the encapsulant 50 may be stacked, e.g., laminated, on the first redistribution substrate 110 on which the first semiconductor chip 10 is positioned. In this case, the paste bumps 155 may be connected to the first bonding pad 111 on the upper surface of the first redistribution substrate 110.

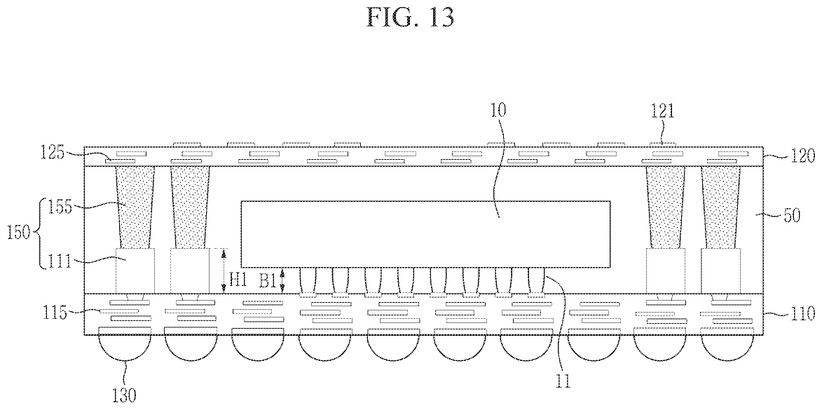

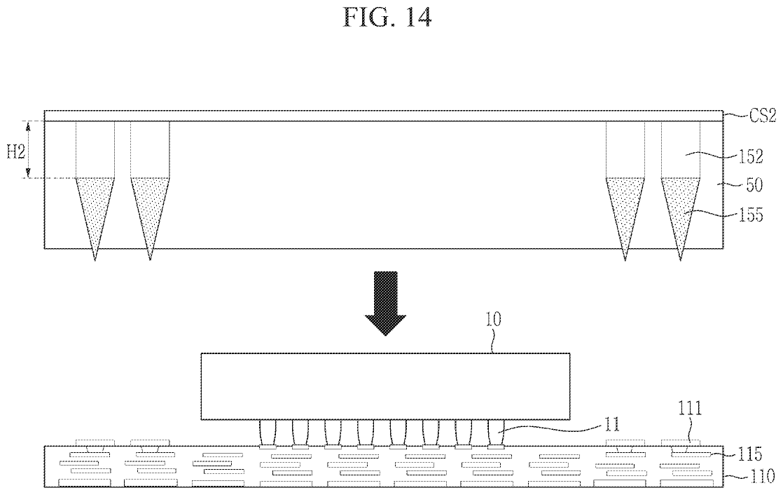

In an embodiment, when the first semiconductor chip 10 is thick, the connection structure 150 (see FIG. 13) may have a height corresponding to a thickness of the first semiconductor chip 10. According to an embodiment, at least one of upper and lower portions of the paste bump 155 may further include a plating portion. In addition, according to an embodiment, the paste bump 155 and the plating portion may be formed of different materials. For example, the plating portion may include a plating material including copper. The plating portion may include at least one of the first bonding pad 111 and the conductive pillar 152 (see FIG. 14).

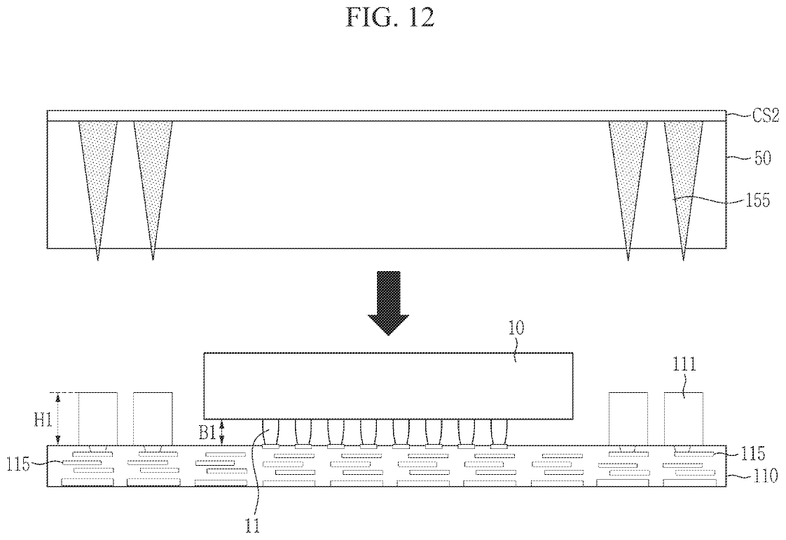

FIG. 12 and FIG. 13 illustrate a fabricating method of a semiconductor package in which a connection structure 150 is formed according to another embodiment. In an embodiment, the first bonding pad 111 may be formed with a height H1. The first bonding pad 111 may have a high level as a plating portion at a lower portion of the paste bump 155.

Referring to FIG. 12, the first bonding pad 111 may be formed on the first redistribution substrate 110 through a photolithography process and a plating process. For example, the first bonding pad 111 may be formed using a photoresist. The first bonding pad 111 may be formed to a height H1 of about 250 μm or less, and according to an embodiment, the first bonding pad 111 may protrude higher than a lower end of the first semiconductor chip 10. In other words, the height H1 of the first bonding pad 111 may be greater than a height B1 of a lower end of the first semiconductor chip 10.

Referring to FIG. 12 and FIG. 13, the second carrier CS2 including the encapsulant 50 and the paste bump 155 penetrating the encapsulant 50 may be stacked on the first redistribution substrate 110 on which the first bonding pad 111 is formed. In this case, the paste bump 155 may be connected to the first bonding pad 111. That is, a height of the connection structure 150 may be increased by a height of the first bonding pad 111. Accordingly, the height of the connection structure 150 may be greater than a thickness of the first semiconductor chip 10.

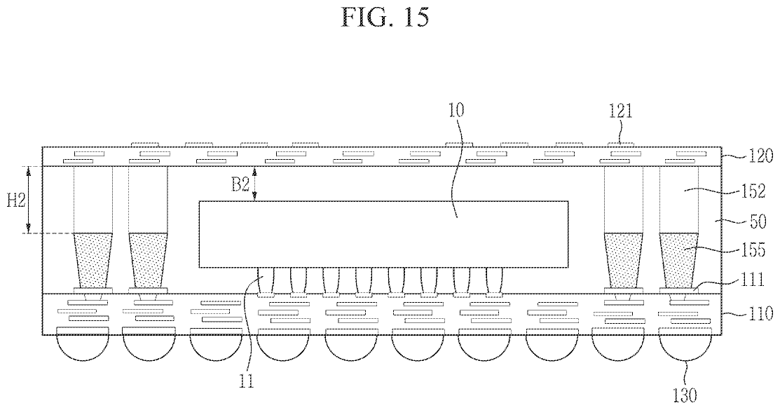

FIG. 14 and FIG. 15 illustrate a fabricating method of a semiconductor package in which a connection structure 150 is formed according to another embodiment. In an embodiment, a conductive pillar 152 may be formed as a plating portion at an upper portion of the paste bump 155.

Referring to FIG. 14, the conductive pillar 152 having a height H2 may be formed on the second carrier CS2. In an embodiment, the paste bump 155 may be formed (e.g., printed) on the conductive pillars 152. The conductive pillar 152 may include, for example, a copper post (Cu post). The conductive pillar 152 may be formed on the second carrier CS2 through, for example, a photolithography process and a plating process. The paste bump 155 may be printed on the conductive pillar 152. A height of the connection structure 150 may be increased by the height of the conductive pillar 152. Accordingly, since the height of the connection structure 150 may be extended, the height of the connection structure 150 may be greater than a height of the first semiconductor chip 10.

The height H2 of the conductive pillar 152 may be about 250 μm or less, and according to an embodiment, the conductive pillar 152 may protrude downward from an upper end of the first semiconductor chip 10.

Referring to FIG. 14 and FIG. 15, the second carrier CS2, including the conductive pillar 152 and the encapsulant 50 through which the paste bump 155 extends may be stacked on the first redistribution substrate 110. In this case, the paste bump 155 may be connected to the first bonding pad 111. That is, a height of the connection structure 150 may be increased by the height H2 of the conductive pillar 152. Accordingly, the height of the connection structure 150 may be greater than the first semiconductor chip 10 having a large thickness. In other words, the height H2 of the conductive pillar 152 may be greater than a height B2 between an upper end of the first semiconductor chip 10 and the second redistribution substrate 120.

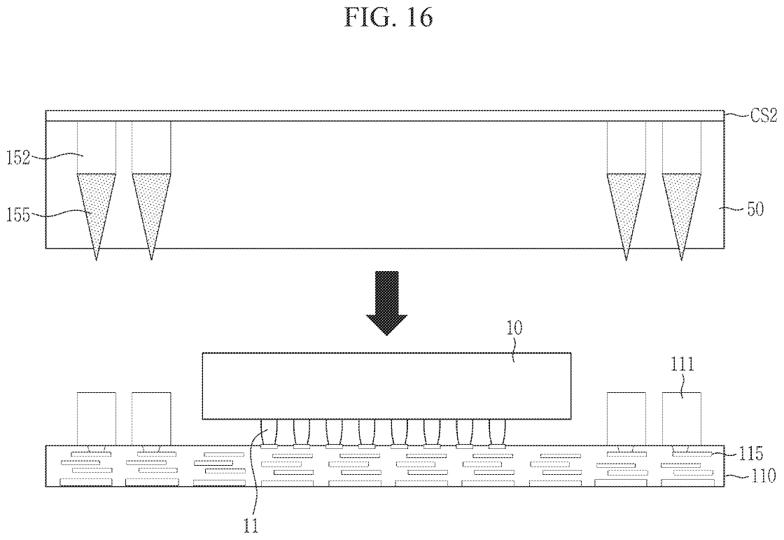

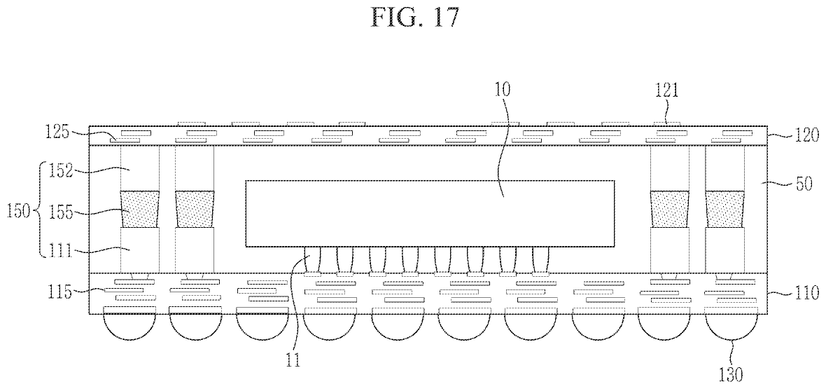

FIG. 16 and FIG. 17 illustrate a fabricating method of a semiconductor package according to an embodiment. In an embodiment, the connection structure 150 may include the conductive pillars 152 and the first bonding pads 111 as plating portions at upper and lower portions of the paste bumps 155, respectively.

Referring to FIGS. 16 and 17, the connection structure 150 may include the paste bump 155, the conductive pillar 152, and first bonding pad 111. According to an embodiment, the conductive pillar 152 may protrude below an upper end of the first semiconductor chip 10, and the first bonding pad 111 may protrude above a lower end of the first semiconductor chip 10. Accordingly, since the height of the connection structure 150 may greater than the first semiconductor chip 10 having a large thickness.

In an embodiment, a package-on-package (POP) structure may be implemented using the semiconductor package 100 of various embodiments described above.

FIG. 18 illustrates a semiconductor package having a package-on-package (POP) structure according to an embodiment. Referring to FIG. 18, in a second semiconductor package 200 according to an embodiment, the second semiconductor chip 20 may be positioned on the second redistribution substrate 120. Alternatively, in the second semiconductor package 200 of an embodiment, an upper package P2 may be positioned on the second redistribution substrate 120. Hereinafter, a case where the upper package P2 is positioned on the second redistribution substrate 120 will be described as an example.

The upper package P2 may be electrically connected to the second redistribution substrate 120. For example, the bonding member 140 at a lower end of the upper package P2 may be bonded to the second bonding pad 121 on an upper surface of the second redistribution substrate 120. The bonding member 140 may electrically connect the upper package P2 to the second redistribution substrate 120. The package bump 130 may include solder, e.g., a solder ball or a solder bump.

Although not illustrated in the drawing, the bonding member 140 may include a bonding wire, for example. The upper package P2 may be electrically connected to the second redistribution substrate 120 through bonding wires (not illustrated). For example, the upper package P2 may be electrically connected to the second redistribution substrate 120 by bonding a bonding wire electrically connected to the upper package P2 to the second bonding pad 121.

Although some embodiments of inventive concepts have been discussed with reference to accompanying figures, it will be understood that various changes in form and details may be made therein without departing from the spirit and scope of inventive concepts. Accordingly, example embodiments of the inventive concepts should be considered in all respects as illustrative and not restrictive, with the spirit and scope of the inventive concepts defined in the following claims.

### DESCRIPTION OF SYMBOLS

10 first semiconductor chip
11 chip bump
20 second semiconductor chip
50 encapsulant
100 first semiconductor package
110 first redistribution substrate
111 first bonding pad
120 second redistribution substrate
121 second bonding pad
130 package bump
140 bonding member
150 connection structure
152 conductive pillar
153 plating portion
155 paste bump
200 second semiconductor package

1. A semiconductor package comprising:
a first redistribution substrate;
a semiconductor chip disposed on the first redistribution substrate;
a second redistribution substrate;
an encapsulant disposed between the first redistribution substrate and the second redistribution substrate and encapsulating the semiconductor chip; and
a connection structure disposed in the encapsulant, connecting an upper surface of the first redistribution substrate and a lower surface of the second redistribution substrate, and including a paste bump.

2. The semiconductor package of claim 1, wherein the connection structure electrically connects the first redistribution substrate and the second redistribution substrate.

3. The semiconductor package of claim 1, wherein the paste bump has a cross-sectional area that decreases in a plan view from an upper portion to a lower portion.

4. The semiconductor package of claim 1, wherein the connection structure further includes a plating portion on at least one of an upper portion and a lower portion of the paste bump, and the paste bump includes a material different than that of the plating portion.

5. The semiconductor package of claim 1, wherein the connection structure further includes a first bonding pad on the upper surface of the first redistribution substrate, and the paste bump connects the first bonding pad and the second redistribution substrate.

6. The semiconductor package of claim 5, further comprising a chip bump between the first redistribution substrate and the semiconductor chip,
wherein the first bonding pad protrudes above a lower end of the semiconductor chip on the chip bump.

7. The semiconductor package of claim 1, wherein the connection structure further includes a conductive pillar extending from the lower surface of the second redistribution substrate, and the paste bump connects the conductive pillar and the first redistribution substrate.

8. The semiconductor package of claim 7, wherein the conductive pillar protrudes below an upper end of the semiconductor chip.

9. The semiconductor package of claim 1, further comprising:
an upper package disposed on an upper surface of the second redistribution substrate; and
a bonding member of the upper package connected to a second bonding pad disposed on the upper surface of the second redistribution substrate to electrically connect the upper package to the second redistribution substrate.

10. The semiconductor package of claim 1, further comprising a package bump disposed on a lower surface of the first redistribution substrate.

11. A semiconductor package comprising:
a first redistribution substrate;
a semiconductor chip disposed on the first redistribution substrate;
a chip bump connecting the first redistribution substrate and the semiconductor chip;
a second redistribution substrate;
an encapsulant disposed between the first redistribution substrate and the second redistribution substrate and encapsulating the semiconductor chip;
a connection structure including a paste bump penetrating the encapsulant and electrically connecting an upper surface of the first redistribution substrate and a lower surface of the second redistribution substrate, wherein at least a portion of the paste bump has a cross-sectional area decreasing in a plan view from an upper portion to a lower portion; and
a package bump disposed on a lower surface of the first redistribution substrate.

12. The semiconductor package of claim 11, wherein the paste bump includes an alloy comprising tin.

13. A method of fabricating a semiconductor package, the method comprising:
preparing a first redistribution substrate on which a semiconductor chip is disposed;
preparing an encapsulant comprising a pillar structure including a paste bump penetrating the encapsulant; and
encapsulating the semiconductor chip by stacking the encapsulant on the first redistribution substrate.

14. The method of claim 13, wherein the preparing of the first redistribution substrate comprises:
forming a first redistribution substrate on a first carrier; and
bonding the semiconductor chip on the first redistribution substrate.

15. The method of claim 13, wherein the preparing of the encapsulant comprises:
forming the pillar structure by printing the paste bump on a second carrier; and
forming the encapsulant, in a semi-cured state, on the second carrier, wherein the pillar structure penetrates the encapsulant.

16. The method of claim 15, wherein the forming of the pillar structure further comprises:
forming a conductive pillar on the second carrier; and
printing the paste bump on the conductive pillar.

17. The method of claim 13, wherein the preparing of the encapsulant comprises:
forming a second redistribution substrate on a second carrier;
forming the pillar structure by printing the paste bump on the second redistribution substrate; and
forming the encapsulant, in a semi-cured state, on the second redistribution substrate, wherein the pillar structure penetrates the encapsulant.

18. The method of claim 17, wherein the forming of the pillar structure further comprises:
forming a conductive pillar on the second redistribution substrate; and
printing the paste bump on the conductive pillar.

19. The method of claim 13, wherein in the encapsulating, the paste bump is connected to a bonding pad positioned on the first redistribution substrate.

20. The method of claim 13, further comprising forming a second redistribution substrate on the encapsulant.
